(19) United States
(12) Patent Application Publication
(10) Pub. No.: US 2012/0188013 A1
(43) Pub. Date: Jul. 26, 2012

(54) RECEIVING CIRCUIT, SEMICONDUCTOR DEVICE INCLUDING THE SAME, AND INFORMATION PROCESSING SYSTEM

(75) Inventors: Yuji USHIO, Masuda (JP); Daisuke Hamano, Hachioji (JP); Tatsunori Usugi, Inagi (JP)

(73) Assignee: HITACHI, LTD.

(21) Appl. No.: 13/349,236

(22) Filed: Jan. 12, 2012

(30) Foreign Application Priority Data
Jan. 25, 2011 (JP) 2011-012475

(51) Int. Cl. H03F 3/45

(52) U.S. Cl. 330/253

(57) ABSTRACT

In a receiving circuit, and in a semiconductor device and an information processing system including the receiving circuit, the receiving circuit is configured to amplify a high-speed signal by a greater gain than a low-speed signal with a low electric power consumption. The receiving circuit includes a first amplifier and a second amplifier having a cutoff frequency lower than a cutoff frequency of the first amplifier. A received signal is inputted to the first amplifier and the second amplifier, an output from the second amplifier is subtracted from an output from the first amplifier, and a result is outputted from the receiving circuit.

### CLAIM OF PRIORITY

The present application claims priority from Japanese patent application JP 2011-012475 filed on Jan. 25, 2011, the content of which is hereby incorporated by reference into this applications.

### FIELD OF THE INVENTION

The present invention relates to a receiving circuit, a semiconductor device, and an information processing system, and more particularly, to a receiving circuit useful in serial transmission, a semiconductor device including such a receiving circuit, and an information processing system.

### BACKGROUND OF THE INVENTION

In an information processing system, serial transmission is used to transmit data between boards. In the serial transmission, it is known that, as the transmission rate increases, a transmission loss increases, which can result in an increase in ISI (Intersymbol Interference) which can in turn result in an increase in BER (Bit Error Rate). In the serial transmission, data patterns may include a sequence of continuously alternating 0s and 1s, and a sequence of continuous 0s or continuous 1s. A highest transmission rate is possible for a pattern including a sequence of continuously alternating 0s and 1s, and the transmission rate decreases with the number of continuous 0s or 1s.

To compensate for a transmission loss in high-speed data transmission, it is known to use a receiving circuit having an RC feedback circuit to amplify high-frequency components of a data signal (see, for example, Japanese Unexamined Patent Application Publication No. 2009-171406).

### SUMMARY OF THE INVENTION

In the receiving circuit including the RC feedback circuit, when a low-speed signal including a sequence of continuous 0s or 1s is received, a large power loss due to a resistor of the RC feedback circuit occurs. On the other hand, when a high-speed signal including a sequence of continuously alternating 0s and 1s received, a large power loss occurs to charge/discharge a capacitor of the RC feedback circuit. In particular, a power loss in charging/discharging a capacitor in receiving a high-speed signal can cause a significant increase in electric power consumed by the receiving circuit in the serial transmission. In view of the above, it is an object of the present invention to provide a receiving circuit capable of amplifying a high-speed signal by a greater gain than a low-speed signal with reduced electric power consumption. It is another object of the present invention to provide a semiconductor device and an information processing system including such a receiving circuit.

According to one aspect of the present invention, a receiving circuit includes a first amplifier; and a second amplifier having a cutoff frequency lower than a cutoff frequency of the first amplifier, in which a received signal is inputted to the first amplifier and the second amplifier, an output from the second amplifier is subtracted from an output from the first amplifier, and a result is outputted.

According to another aspect of the present invention, there is provided a semiconductor device including a receiving circuit such as that described above.

According to still another aspect of the present invention, there is provided an information processing system including a receiving circuit such as that described above.

According to the aspects of the present invention, it possible to amplify a high-speed signal by a greater gain than a low-speed signal while reducing the electric power loss.

### BRIEF DESCRIPTION OF THE DRAWINGS

FIG. 1 is a diagram illustrating an example of an information processing system including a plurality of daughter boards each including a receiving circuit for use in data transmission among them according to an embodiment of the invention;

FIG. 2 is a diagram illustrating an example of a configuration of a data transmission system in which data is transmitted from a semiconductor device on one daughter board to a semiconductor device including a receiving circuit according to an embodiment of the invention on another daughter board;

FIG. 3 is a diagram illustrating an example of a receiving circuit according to an embodiment of the invention;

FIG. 4 is a diagram illustrating an example of a differential detector used in a receiving circuit according to an embodiment of the invention;

FIG. 5 is a diagram illustrating an example of a frequency characteristic of a transmission line;

FIG. 6 is a diagram illustrating an example of a gain characteristic of a receiving circuit according to an embodiment of the invention;

FIG. 7 is a diagram illustrating an example of a gain characteristic of a receiving circuit according to an embodiment of the invention;

FIG. 8 is a diagram illustrating examples of waveforms associated with a receiving circuit according to an embodiment of the invention; and

FIG. 9 is a diagram illustrating an example of a waveform including an offset and an example of a waveform including no offset.

### DETAILED DESCRIPTION OF THE PREFERRED EMBODIMENTS

The present invention is described in further detail below with reference to embodiments.

### First Embodiment

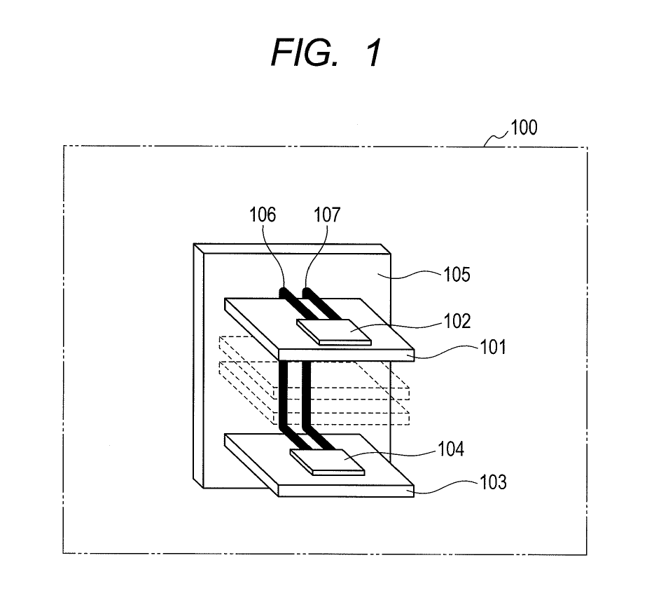

FIG. 1 is a diagram illustrating an example of an information processing system including a receiving circuit according to a first embodiment of the invention. The information processing system 100 shown in FIG. 1 includes an integrated circuit (LSI) 102 which is a semiconductor device disposed on a daughter board 101, an integrated circuit (LSI) 104 which is a semiconductor device disposed on a daughter board 103, and a backplane 105. The integrated circuit 102 and the integrated circuit 104 each include, as one of circuits disposed therein, a serializer/deserializer (SerDes) circuit including the receiving circuit according to an embodiment of the invention. The daughter board 101 and the daughter board 103 are printed circuit-boards each including an integrated circuit mounted thereon and each configured to be inserted in one of connectors disposed on a backplane 105. The backplane 105 is a printed circuit board including a plurality of connectors and serves as a base for properly connecting a plurality of other printed circuit boards such as daughter boards. A function can be extended by connecting a daughter board including an integrated circuit for extending the function to a connector of the backplane 105.

Data output from the integrated circuit 102 on the daughter board 101 is outputted via the serializer/deserializer circuit over a signal line 106 printed on the daughter board 101, the backplane 105, and the daughter board 103, and the data is inputted to the serializer/deserializer circuit of the integrated circuit 104. Conversely, data output from the integrated circuit 104 via the serializer/deserializer circuit is inputted to the serializer/deserializer circuit of the integrated circuit 102 via a signal line 107. That is, data is transmitted between the integrated circuit 102 and integrated circuit 104 via the signal line 106 and the signal line 107 serving as transmission lines. The information processing system 100 shown in FIG. 1 may further include, for example, a server, a router, and/or a storage device, etc. In other words, the information processing system 100 shown in FIG. 1 may be a server system, a router system, or a storage system.

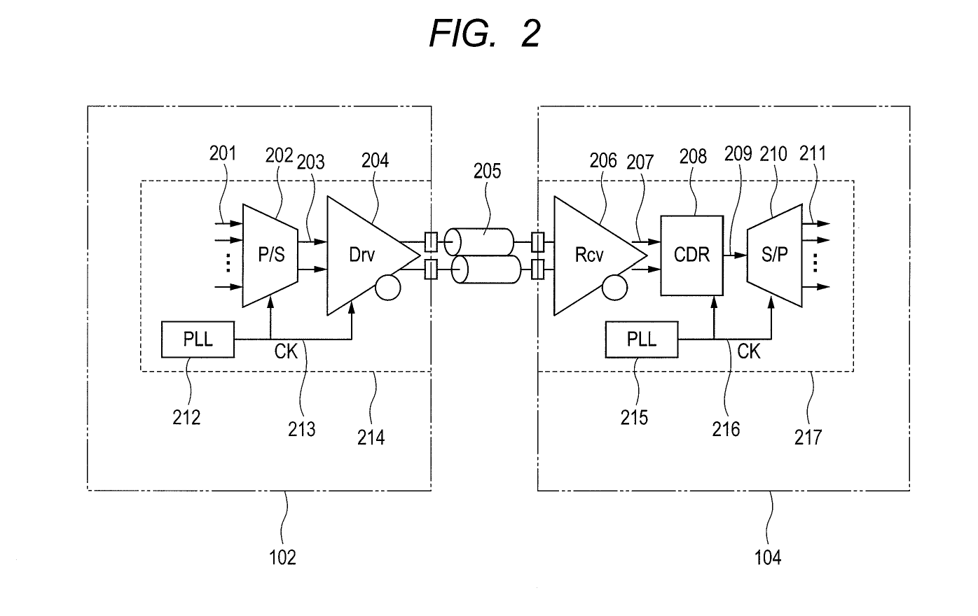

FIG. 2 illustrates an example of a configuration of a transmission system in which data is transmitted from the integrated circuit 102 to the integrated circuit 104 via the signal line 106 in the information processing system 100 shown in FIG. 1. The integrated circuit 102 on a transmitting side includes a transmitting-side serializer/deserializer circuit 214. The integrated circuit 104 on a receiving side includes a receiving-side serializer/deserializer circuit 217. The transmitting-side serializer/deserializer circuit 214 includes a parallel-serial data conversion circuit (P/S) 202, an output circuit (Drv) 204, and a phase locked loop circuit (PLL) 212. The receiving-side serializer/deserializer circuit 217 includes a receiving circuit (Rcv) 206 according to an embodiment of the invention, a clock data recovery circuit (CDR) 208, a serial-parallel data conversion circuit (S/P) 210, and a phase locked loop circuit (PLL) 215.

The phase locked loop circuit (PLL) 212 supplies a clock signal (CK) 213 to the parallel-serial data conversion circuit (P/S) 202 and the output circuit (Dry) 204. The parallel-serial data conversion circuit (P/S) 202 convers parallel data 201 into serial data 203 according to the clock signal (CK) 213. The output circuit (Dry) 204 outputs the serial data 203 received from the parallel-serial data conversion circuit (P/S) 202 to a transmission line 205. Note that the transmission line 205 corresponds to the signal line 106 shown in FIG. 1.

The phase locked loop (PLL) circuit 215 supplies the clock signal (CK) 216 to the clock data recovery circuit (CDR) 208 and the serial-parallel data conversion circuit (S/P) 210. The receiving circuit (Rcv) 206 amplifies the serial data input via the transmission line 205. The clock data recovery circuit (CDR) 208 reproduces serial data 209 while adjusting a phase between serial data 207 from the receiving circuit 206 and the supplied clock signal (CK) 216, and outputs the resultant reproduced serial data 209 to the serial-parallel data conversion circuit (S/P) 210. The serial-parallel data conversion circuit (S/P) 210 converts the serial data 209 into parallel data 211, and the resultant parallel data 211 to the receiving-side integrated circuit 104.

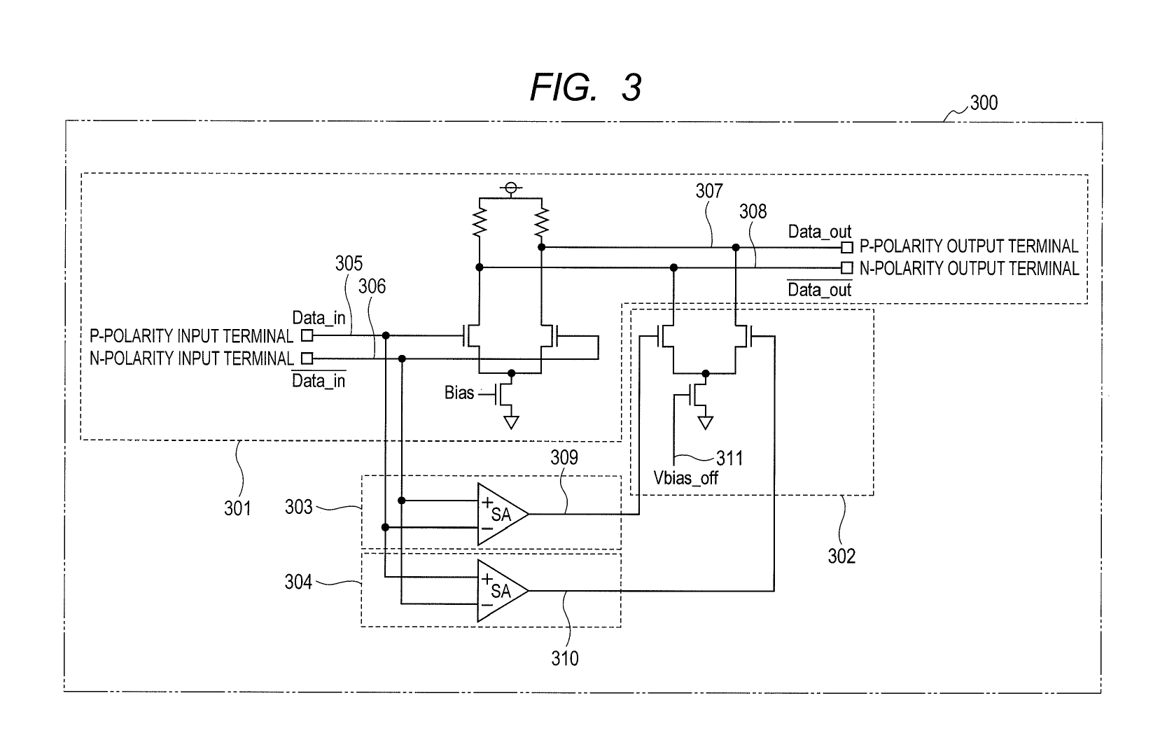

FIG. 3 illustrates a receiving circuit 300, which is a specific example of the receiving circuit 206 according to an embodiment of the invention. The receiving circuit 300 includes a differential amplifier circuit 301, a differential amplifier circuit 302, a differential detection circuit 303, and a differential detection circuit 304.

The differential amplifier circuit 301 and the differential amplifier circuit 302 are each configured in current mode logic (CML). In these differential amplifier circuits 301 and 302, an operating region and a frequency characteristic thereof are determined mainly by a load resistance and a current flowing through a current source transistor. The differential detection circuit 303 and the differential detection circuit 304 are each similar in configuration to a commonly-used operational amplifier, and each have an inverting input terminal (−), a non-inverting input terminal (+), and an output terminal. In each differential detection circuit, a difference between voltages applied to the inverting input terminal (−) and the non-inverting input terminal (+) is amplified by a gain of the operational amplifier, and the amplified voltage is outputted at the output terminal.

A P-polarity input terminal 305 is a terminal to which a signal with one phase of data given via the transmission line 205 is inputted, while an N-polarity input terminal 306 is a terminal to which a signal with the other phase of the data given via the transmission line 205 is inputted. The data signal input to the N-polarity input terminal 306 is differentially amplified and output from a P-polarity output terminal 307, while the data signal input to the P-polarity input terminal 305 is differentially amplified and output from an N-polarity output terminal 308.

As described above, the data signal with one phase of the data supplied via the transmission line 205 is inputted to the P-polarity input terminal 305 of the differential amplifier circuit 301, and the data signal with the other phase of the data supplied via the transmission line 205 is inputted to the N-polarity input terminal 306 of the differential amplifier circuit 301. The result of the differential amplification thereof is outputted from the P-polarity output terminal 307 and the N-polarity output terminal 308.

The P-polarity input terminal 305 of the differential amplifier circuit 301 is connected to the inverting input terminal of the differential detection circuit 303, and the N-polarity input terminal 306 of the differential amplifier circuit 301 is connected to the non-inverting input terminal of the differential detection circuit 303. The differential detection circuit 304 is connected such that the N-polarity input terminal 306 of the differential amplifier circuit 301 is connected to the inverting input terminal of the differential detection circuit 304, while the P-polarity input terminal 305 of the differential amplifier circuit 301 is connected to the non-inverting, input terminal of the differential detection circuit 304.

The differential amplifier circuit 302 is connected such that a drain of a switching transistor, whose switching operation is controlled by a signal supplied from the output terminal 310 of the differential detection circuit 304, is connected to the P-polarity output terminal 307 of the differential amplifier circuit 301, while a drain of a switching transistor, whose switching operation is controlled by a signal supplied from the output terminal 309 of the differential detection circuit 303, is connected to the N-polarity output terminal 308 of the differential amplifier circuit 301.

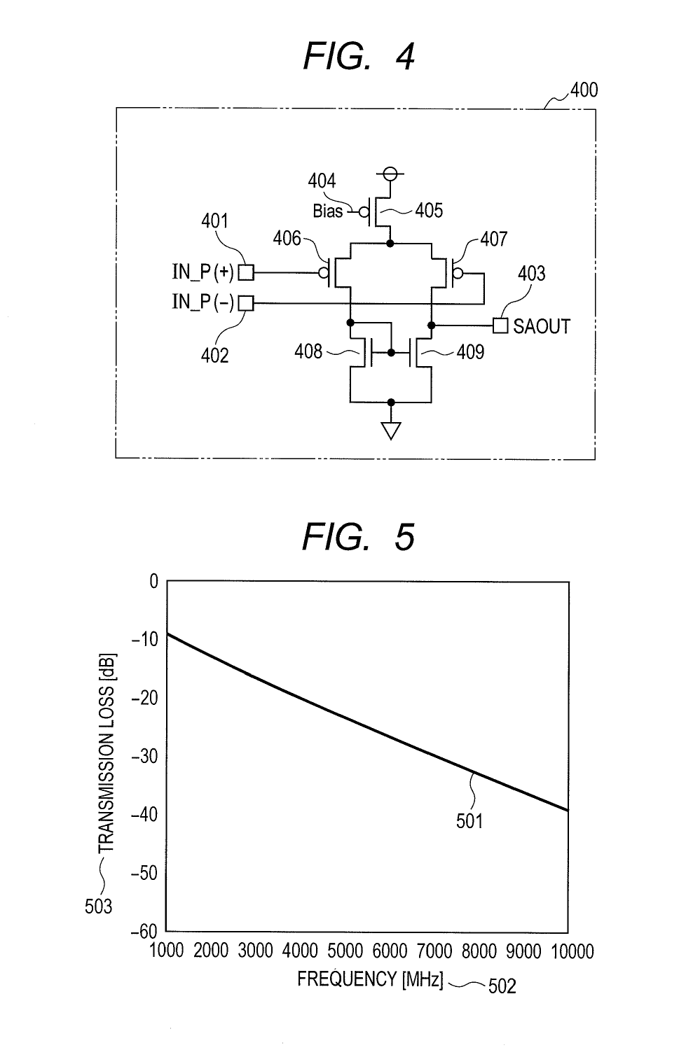

FIG. 4 illustrates an example of a circuit usable in the differential detection circuit 303 and the differential detection circuit 304. The circuit 400 shown in FIG. 4 includes a P-polarity input terminal 401, an N-polarity input terminal 402, an output terminal 403 connected to the differential amplifier circuit 302, a current source transistor 405 to which a gate voltage 404 is applied, a switching transistor 406, a switching transistor 407, a load resistor transistor 408, and a load resistor transistor 409. The P-polarity input terminal 401 is connected to the P-polarity input terminal 305 or the N-polarity input terminal 306. The N-polarity input terminal 402 is connected to the P-polarity, input terminal 305 or the N-polarity input terminal 306. In a case where the P-polarity input terminal 305 is connected to the P-polarity input terminal 401, the N-polarity input terminal 306 is connected to the other input terminal, i.e., the N-polarity input terminal 402. On the other hand, in a case where the N-polarity input terminal 306 is connected to the P-polarity input terminal 401, the P-polarity input terminal 305 is connected to the other input terminal, i.e., N-polarity input terminal 402.

In the circuit 400 shown in FIG. 4, a difference between voltages applied to the P-polarity input terminal 401 and the N-polarity input terminal 402 is amplified by a gain of the operational amplifier, and the amplified voltage is outputted at the output terminal 403. In this amplifying operation, an input-output characteristic, which determines the value of the output voltage at the output terminal 403 is determined by parameters of the current source transistor 405, the switching transistor 406, the switching transistor 407, the load resistor transistor 408, and the load resistor transistor 409. The cutoff frequency of the circuit 400, i.e., the cutoff frequency of the differential detection circuit 303 and the differential detection circuit 304 is set to be lower than the cutoff frequency of the amplifier in the state in which the differential amplifier circuit 302 is connected to the differential amplifier circuit 301, i.e., than the cutoff frequency of the receiving circuit 300. Note that the cutoff frequency of the receiving circuit 300 in the present embodiment refers to the cutoff frequency in the state in which the potential of the output terminals of the differential detection circuit 303 and that of the output terminal of the differential detection circuit 304 are forced to be set to 0 volt, i.e., the cutoff frequency in the state in which the receiving circuit 300 is operated as a simple amplifier without performing an equalization process. In this state, for frequencies higher than the cutoff frequency of the differential detection circuit 303 and the differential detection circuit 304, the gain of the differential detection circuit 303 and the gain of the differential detection circuit 304 fall down to very low levels. Note that in the present embodiment, the circuit 400 used in the differential detection circuit 303 and that used in the differential detection circuit 304 are equal in circuit configuration, and thus the cutoff frequency is substantially equal for both the differential detection circuit 303 and the differential detection circuit 304.

The frequency characteristic of the circuit 400 can be changed by changing parameters of the current source transistor 405, the switching transistor 406, the switching transistor 407, the load resistor transistor 408, and the load resistor transistor 409. For example, by reducing the size of the current source transistor 405, it is possible to reduce the cutoff frequency of the frequency characteristic of the circuit 400. When the size of the load resistor transistor 408 and that of the load resistor transistor 409 are increased, the cutoff frequency of the frequency characteristic of the circuit 400 is reduced.

Next, a description is given below as to a manner in which the receiving circuit 300 shown in FIG. 3 emphasizes a high-speed signal rather than a low-speed signal with a reduced electric power consumption, which is achieved by the circuit configuration including no RC feedback circuit.

FIG. 5 illustrates an example of a frequency characteristic of a transmission line that transmits data output from the transmitting circuit. A vertical axis 503 represents a transmission loss, and a horizontal axis 502 represents a frequency. In this figure, of mixed mode S parameters, a mixed-mode transmission characteristic (SDD21) 501 from a port 1 to a port 2 is plotted. As can be seen in FIG. 5, the attenuation of the transmission line increases with the frequency of the signal.

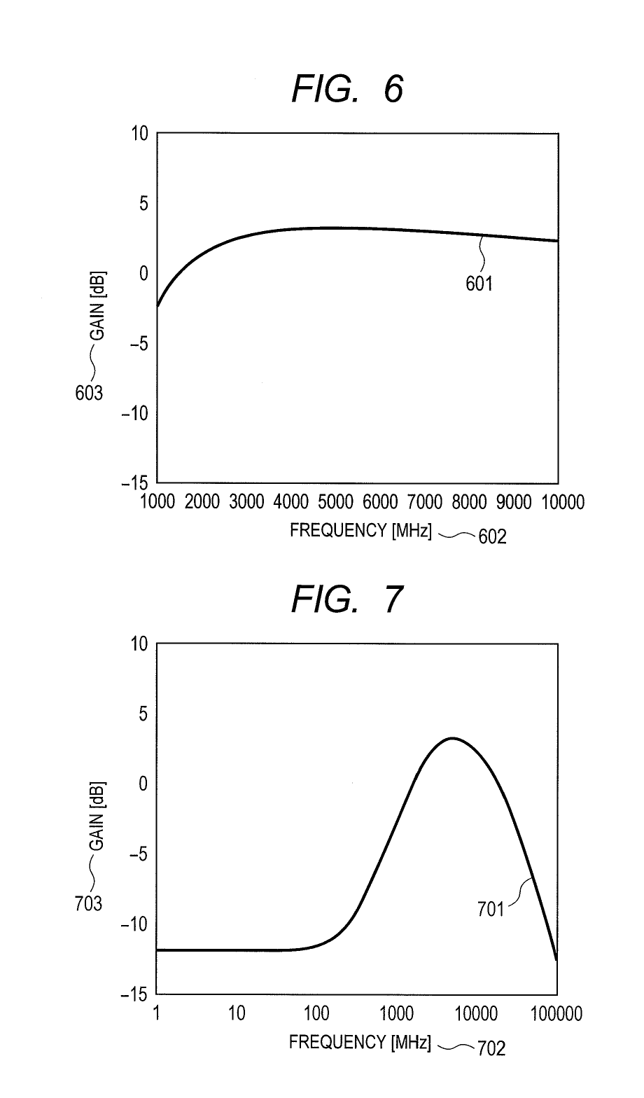

FIG. 6 illustrates a frequency characteristic in terms of an amplitude characteristic of the receiving circuit 300. A vertical axis 603 represents a gain, and a horizontal axis 602 represents a frequency. The amplitude characteristic 601 of the receiving circuit 300 is plotted in this figure. Note that the horizontal axis 602 is expressed in a decimal form, while the vertical axis 603 is expressed in decibels (dB). Ideally, the amplitude characteristic 601 is an inverse function of the characteristic 501 shown in FIG. 5. Although the actual amplitude characteristic 601 is not an exact inverse function of the characteristic 501, the gain increases with increasing frequency, as opposed to the characteristic 501, in a few gigahertz (GHz) band in a frequency band used in the serial transmission. That is, in the few GHz band, the receiving circuit 300 amplifies a signal attenuated by the transmission line such that the gain increases with frequency. In FIG. 7, the amplitude characteristic is plotted over a greater range along the horizontal axis than in FIG. 6. In FIG. 7, a vertical axis 703 represent the gain, a horizontal axis 702 represents the frequency, and an amplitude characteristic 701 of the receiving circuit 300 is plotted. The horizontal axis 702 is expressed on a logarithmic scale.

The receiving circuit 300 can emphasize high-speed signals rather than low-speed signals mainly because the receiving circuit 300 has such a frequency characteristic (amplitude characteristic 701) that the gain is high in a GHz band, i.e., a high-frequency band in the whole frequency band used in the serial transmission shown in FIG. 7, but the gain is low in the lower frequency band. For example, when ½ of the transfer rate of a low-speed signal is equal to 10 MHz and ½ of the transfer rate of a high-speed signal is equal to 5 GHz, the gain for the low-speed signal is about −12 dB and the gain for the high-speed signal is about 3 dB. This difference in gain allows it to perform an equalization process on the signal such that a high-speed signal component in the signal is emphasized, whereby jitter due to ISI is reduced and BER is improved.

In another view point, because the gain is high in the GHz band and the gain is low in the lower frequency band, the amplitude of the amplified low-speed signal can be similar to that of the amplified high-speed signal, which makes it possible to detect the high-speed signal using the same threshold value as that used to detect the low-speed signal. Thus, it is possible to reduce jitters caused by ISI, and it is possible to improve BER. The difference in gain is achieved because the cutoff frequency of the differential detection circuit 303 and the cutoff frequency of the differential detection circuit 304 are set to be lower than the cutoff frequency of the receiving circuit 300, and, besides, in the frequency band lower than the cutoff frequency of the differential detection circuit 303 and the differential detection circuit 304, the output of the differential amplifier circuit 301 is subtracted by the output of the differential amplifier circuit 302 connected to the differential detection circuit 303 and the differential detection circuit 304. To provide another view point, let the differential amplifier circuit 301 be regarded as a first amplifier and let a circuit including the differential detection circuits 303 and 304 and the differential amplifier circuit 302 connected thereto be regarded as a second amplifier. When a received serial transmission signal is inputted to the first amplifier and the second amplifier with a cutoff frequency set to be lower than that of the first amplifier, the output of the first amplifier is subtracted by the output of the second amplifier and the result is outputted as the output of the receiving circuit 300. Because the gain is high in the GHz band and the gain is low in the lower frequency band, the amplitude of the amplified low-speed signal can be similar to that of the amplified high-speed signal, which makes it possible to detect the high-speed signal using the same threshold value as that used to detect the low-speed signal, whereby jitter due to ISI is reduced and it is possible to improve BER.

The reason why the output of the differential amplifier circuit 301 is subtracted by the output of the differential amplifier circuit 302 connected to the differential detection circuit 303 and the differential detection circuit 304 is that inputs/outputs among the differential amplifier circuit 301, the differential amplifier circuit 302, the differential detection circuit 303, and the differential detection circuit 304 are connected such that the subtraction is achieved. More specifically, for example, in the operation of the receiving circuit 300, in a case where the potential of the N-polarity input terminal 306 of the differential amplifier circuit 301 is higher than the potential of the P-polarity input terminal 305, when signals outputs from the differential detection circuits 303 and 304 are inputted to the differential amplifier circuit 302, the output potential at the N-polarity output terminal 308 is lowered greater by the differential amplifier circuit 302 than the potential of P-polarity output terminal 307 is lowered. Conversely, in a case where the potential at the P-polarity input terminal 305 of the differential amplifier circuit 301 is higher than the potential at the N-polarity input terminal 306, when signals output from the differential detection circuits 303 and 304 are inputted to the differential amplifier circuit 302, the output potential at the P-polarity output terminal 307 is lowered greater by the differential amplifier circuit 302 than the potential of the N-polarity output terminal 308 is lowered. That is, of the potentials at the output terminals 307 and 308, a higher one of the two potentials is lowered greater than the other. Therefore, in a frequency range lower than the cutoff frequency of the differential detection circuit 303 and the differential detection circuit 304, when there is a potential difference between the input terminals 305 and 306 of the differential amplifier circuit 301, the potential difference between the output terminals 307 and 308 of the differential amplifier circuit 301 is reduced by the output of the differential amplifier circuit 302, and thus the equalization process described above is achieved. The amount of equalization in the equalization process can be adjusted by changing the gate voltage 311 of the current source transistor of the differential amplifier circuit 302.

In receiving circuits using a conventional RC feedback circuit, to increase the amount of equalization, it is necessary to increase the RC constant with the increasing transmission rate. However, the increase in the RC constant causes an increase in power consumed when charging or discharging occurs. For example, when the transmission rate is 10 Gbps and the power supply voltage is 1.0 volts, if the electric power consumed by the differential amplifier circuit 301 alone is 1 mA, the presence of the RC feedback circuit results in an increase in total electric power by a factor of 1.6 (which is an experimentally determined value), and thus the total electric power consumption is 1.6 mA. In contrast, in the receiving circuit 300 according to the present embodiment of the invention, when the transmission rate is 10 Gbps and the power supply voltage is 1.0 volts, if the electric power consumed only by the differential amplifier circuit 301 is 1 mA, the presence of the differential amplifier circuit 302 results in an increase in electric power by a factor of 1.1, and each of the differential detection circuit 303 and the differential detection circuit 304 results in an increase in electric power by a factor of 1.1, and thus the total electric power consumption is 1.3 mA. In the receiving circuit 300, as described above, because the equalization process is performed without using the RC feedback circuit, the power loss is minimized. Similarly, a reduction in power loss or electric power consumption in serial transmission can be achieved for the integrated circuit 104 including the receiving circuit 300, and for the information processing system 100 including the integrated circuit 104. In particular, in a case where an information processing system includes a multi-lane transmission line to achieve a high transmission efficiency, a great reduction in power consumption can be achieved. In view of the above, the information processing system may be configured, for example, such that the integrated circuit at the transmitting side and the integrated circuit at the receiving side are connected via a 4-lane transmission line, and the integrated circuit at the receiving side includes four receiving circuits 300 each of which is connected to one of the four lanes in the transmission line. In general, as the number of lanes increases, the electric power consumption increases. However, use of the receiving circuit 300 in the information processing system including the multilane transmission line allows a great suppression in increase in the electric power consumption.

Next, a description is given below as to a method of designing the receiving circuit 300 such that a high-efficiency equalization process is achieved using a feed-forward control mechanism. In the design of the differential amplifier circuit 301, parameters are properly determined in terms of the load resistance and the parasitic load resistance, and the sum of the parasitic load capacitance, and the drain capacitance of the differential amplifier circuit 302 connected to the P-polarity output terminal and the N-polarity output terminal such that the cutoff frequency of the receiving circuit 300 is sufficiently high with respect to ½ of the transmission rate and a phase shift does not occur over a range up to ½ of the transmission rate. In the design of the differential detection circuit 303 and the differential detection circuit 304, parameters shown in FIG. 4 are properly determined in terms of the load resistance, the parasitic load resistance, and the sum of the parasitic load capacitance and the gate capacitance of the current source transistor of the differential amplifier circuit 302 such that the differential detection circuit 303 and the differential detection circuit 304 have an amplitude characteristic as similar as the amplitude characteristic of the frequency characteristic of the transmission line shown in FIG. 5. That is, the parameters are determined in the above-described manner such that the receiving circuit 300 has a frequency characteristic having a passband in a high-frequency band as indicated by the plot 701 in FIG. 7.

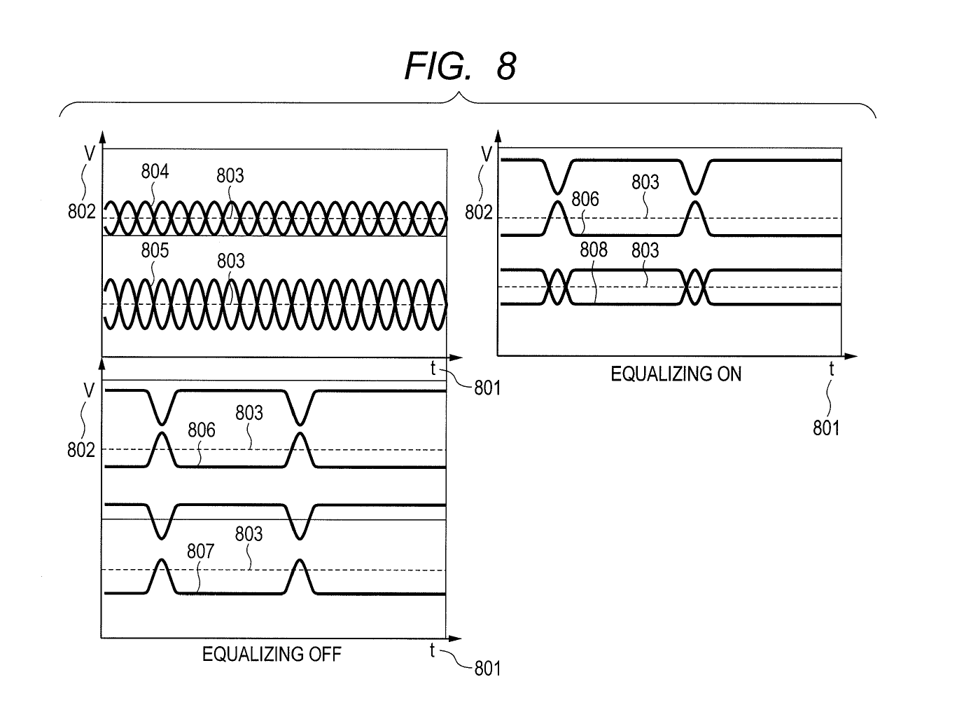

FIG. 8 is a diagram illustrating time-domain waveforms of various signals in the receiving circuit 300. In the figure, 801 denotes a time expressed along a horizontal axis, 802 denotes a voltage expressed along a vertical axis, and 803 denotes a threshold value, and an input waveform 804, an output waveform 805, an input waveform 806, an output waveform 807, and an output waveform 808 are plotted. There are three time axes 801, but they all indicate the same time scale. There are three voltage axes 802, but they all indicate the same voltage scale. The threshold values 803 all indicate the same voltage value.

When the input waveform 804 is given, if the input waveform 804 is simply passed through the differential amplifier circuit 301 shown in FIG. 3 without being subjected to the equalization process described above, then the output waveform 805 is obtained as an output waveform. In this example, a P-polarity waveform and an N-polarity waveform in the input waveform 804 cross each other, and thus the resultant output waveform 805 is similar in shape to the input waveform 804 with an amplified amplitude.

The output waveform 807 also indicates an output waveform obtained when the input waveform 806 is simply passed through the differential amplifier circuit 301 shown in FIG. 3 without being subjected to the equalization process described above. However, in this example, a P-polarity waveform and an N-polarity waveform in the input waveform 806 do not cross each other, and thus the resultant output waveform 807 is out of the operating region of the differential amplifier circuit 301 and a P-polarity waveform and an N-polarity waveform in the output waveform 807 do not cross each other.

The output waveform 808 indicates an output waveform obtained when the input waveform 806 is passed through the receiving circuit 300 and subjected to the equalization process described above. Although a P-polarity waveform and an N-polarity waveform in the input waveform 806 do not cross each other, the resultant output waveform 808 has a shape in which a P-polarity waveform and an N-polarity waveform cross each other, which an effect provided by the equalization process described above. As can be seen from these figures, the equalization process allows the receiving circuit 300 to detect the signal using the same threshold value regardless of whether the signal includes a sequence of continuous 0s or 1s (low-speed signal) or the signal includes a sequence of continuously alternating 0s and 1s (high-speed signal).

The circuit shown in FIG. 3 also has an offset cancelling function in addition to the equalization function. The offset cancelling function may be realized as follows.

In the differential transmission, the difference between the P-polarity amplitude and the N-polarity amplitude, i.e., the P-polarity amplitude minus the N-polarity amplitude or the N-polarity amplitude minus the P-polarity amplitude is transmitted as an amplitude waveform. If there is a shift between the P-polarity and the N-polarity in terms of the amplitude, the potential of the center of the amplitude, the skew, the duty, etc., an offset between the P-polarity and the N-polarity (hereinafter, referred to simply as a P-N offset) occurs. The P-N offset can produce common-mode noise, and thus the P-N offset is one of factors that should be suppressed in the serial transmission. The shift between the P-polarity and the N-polarity in terms of the amplitude, the center of the amplitude, the skew, the duty, and the like are mainly caused by variations or errors of circuit parameters, and it is difficult to completely delete such shifts described above. One known technique to handle the P-N offset is to configure the receiving circuit to have a function of cancelling the P-N offset. More specifically, in this technique, the difference in amplitude between the P-polarity and the N-polarity is detected, and the center of the amplitude of a polarity having a shift from a reference threshold value is corrected.

In the present embodiment of the invention, the receiving circuit 300 is configured in the above-described manner. That is, the P-polarity input terminal 305 and the N-polarity input terminal 306 (which are terminals to which the received data is inputted) of the differential amplifier circuit 301 are connected to the inverting input terminal and the non-inverting input terminal of the differential detection circuit 303 and the differential detection circuit 304 such that the P-polarity input terminal 305 is connected to the inverting input terminal of one of the differential detection circuits 303 and 304 and to the non-inverting input terminal of the other one, while the N-polarity input terminal 306 is connected to the remaining input terminals of the respective differential detection circuits 303 and differential detection circuit 304 so that the P-N offset value is detected and the detected value is transmitted to the pair of switching transistors forming the differential amplifier circuit 302 and thus the amplitude of the data is equalized and the offset is cancelled. Therefore, an additional special circuit or mechanism dedicated to cancelling the offset is not necessary. This is advantageous in achieving a low BER and a low power consumption. Thus, in addition to a reduction in electric power achieved by eliminating the RC feedback circuit, a further reduction in electric power is achieved by eliminating the additional special mechanism for cancelling the offset.

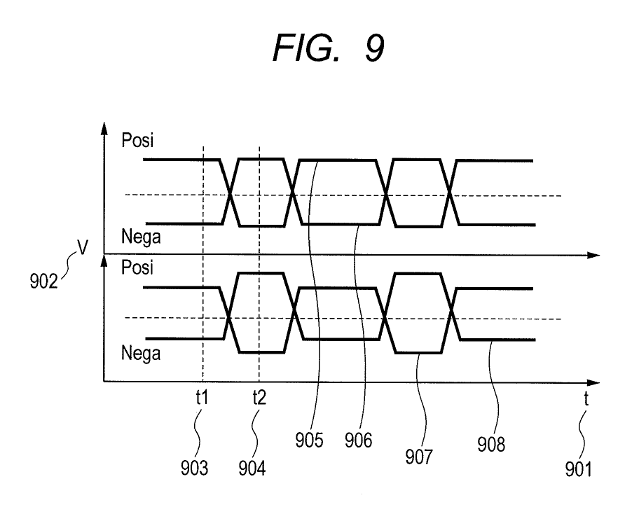

FIG. 9 illustrates a comparison between a set of a P-polarity waveform and an N-polarity waveform with an offset input to the receiving circuit and a set of a P-polarity waveform and an N-polarity waveform with no offset. In FIG. 9, a horizontal axis is a time axis 901, while a vertical axis is a voltage axis 902. A P-polarity waveform 905 and an N-polarity waveform 906 plotted in FIG. 9 have not offset, while a P-polarity waveform 907 and an N-polarity waveform 908 have an offset. When there is an offset, |Vp−Vn| at a time t1 (Vp>Vn) is different from |Vp−Vn| at a time t2 (Vp<Vn). On the other hand, when there is no offset, |Vp−Vn| is equal at the time t1 and at the time t2.

When the waveforms 905 and 906 with no offset shown in FIG. 9 are inputted, a detected voltage output at time t2 by the differential detection circuit 303 in the receiving circuit 300 is equal to a detected voltage output at time t1 by the differential detection circuit 304, and thus equal currents are drawn by the differential amplifier circuit 302. On the other hand, when the waveforms 907 and 908 with the offset are inputted, a detected voltage output at time t2 by the differential detection circuit 303 in the receiving circuit 300 is different from a detected voltage output at time t1 by the differential detection circuit 304, and a greater current is drawn at the P-polarity output terminal 307 by differential amplifier circuit 302 than at the N-polarity output terminal 308, and thus an offset cancelling effect is achieved.

As described above, the receiving circuit 300 shown in FIG. 3 includes the equalizer circuit which operate's with low electric power and which also has the offset cancelling function. Unnecessity of an additional dedicated offset cancelling circuit, which is realized in the form of a separate circuit in conventional technology, makes it possible to achieve a further reduction in electric power consumption. Furthermore, the integrated circuit 104, which is a semiconductor device including the receiving circuit 300, and the information processing system 100 including the integrated circuit 104 also have a feature that serial transmission is possible with reduced electric power consumption. Although in the present embodiment, the output from the receiving circuit 206 is inputted to the CDR circuit 208, the receiving circuit according to the present embodiment of the invention may be applied in other ways. For example, the output of the receiving circuit 206 may be directly connected to an input of an output circuit similar in circuit configuration to the output circuit 204 whereby it becomes possible to process the data input to the receiving circuit 206 such that after the input is subjected to the equalization process and the offset cancelling process according to the present embodiment of the invention, and the resultant data is outputted from the output circuit similar to the output circuit 204 without performing the retiming process, by the CDR.

Although the present invention has been described above with reference to embodiments, the invention is not limited to those embodiments. It is clear that many modifications are possible without departing from the spirit and scope of the invention.

What is claimed is:

1. A receiving circuit comprising:
a first differential amplifier circuit including a P-polarity input terminal, an N-polarity input terminal, a P-polarity output terminal, and an N-polarity output terminal and configured such that a received signal is inputted differentially to the P-polarity input terminal and the N-polarity input terminal and a resultant amplified signal is differentially output from the P-polarity output terminal and the N-polarity output terminal;
a second differential amplifier circuit including a first differential output terminal connected to the P-polarity output terminal of the first differential amplifier circuit, a second differential output terminal connected to the N-polarity output terminal of the first differential amplifier, a first input terminal on a side of the first differential output terminal, and a second input terminal on a side of the second differential output terminal;
a first differential detection circuit including an inverting input terminal connected to the P-polarity input terminal of the first differential amplifier circuit, a non-inverting input terminal connected to the N-polarity input terminal of the first differential amplifier circuit, and an output terminal connected to the second input terminal of the second differential amplifier circuit; and
a second differential detection circuit including a non-inverting input terminal connected to the P-polarity input terminal of the first differential amplifier circuit, an inverting input terminal connected to the N-polarity input terminal of the first differential amplifier circuit, and an output terminal connected to the first input terminal of the second differential amplifier circuit;
wherein the first differential detection circuit and the second differential detection circuit both have a cutoff frequency lower than a cutoff frequency of the receiving circuit.

2. The receiving circuit according to claim 1, wherein the receiving circuit has a sub frequency band within a frequency band of the received signal and a gain of the receiving circuit increases with increasing frequency in the sub frequency band.

3. The receiving circuit according to claim 1, wherein the P-polarity input terminal and the N-polarity input terminal of the first differential amplifier circuit are connected to a serial transmission line.

4. The receiving circuit according to claim 1, wherein the second differential amplifier circuit includes a current source transistor capable of providing an adjustable current flowing therethrough.

5. A semiconductor device comprising:
a receiving circuit according to claim 1;
a clock data recovery circuit to which an output from the receiving circuit is inputted; and
a serial-parallel data conversion circuit to which an output from the clock data recovery circuit is inputted.

6. A semiconductor device comprising:
a receiving circuit according to claim 1.

7. An information processing system comprising:
a semiconductor device according to claim 5.

8. An information processing system comprising:
a semiconductor device according to claim 6.

9. An information processing system comprising:
a semiconductor device including a plurality of receiving circuits according to claim 1,
wherein the semiconductor device is connected to a multi-lane transmission line.

10. A receiving circuit comprising:
a first amplifier; and
a second amplifier having a cutoff frequency lower than a cutoff frequency of the first amplifier,
wherein a received signal is inputted to the first amplifier and the second amplifier, and an output from the second amplifier is subtracted from an output from the first amplifier, and a result is outputted from the receiving circuit.

11. A semiconductor device comprising:
a receiving circuit according to claim 10.

12. An information processing system comprising:
a semiconductor device according to claim 11.

13. An information processing system comprising:
a semiconductor device including a plurality of receiving circuits according to claim 10,
wherein the semiconductor device is connected to a multi-lane transmission line.
